(19) United States
(12) Patent Application Publication
(10) Pub. No.: US 2026/0018982 A1
(43) Pub. Date: Jan. 15, 2026

(54) A SWITCHING CONVERTER TO REDUCE OVERSHOOTING IN OUTPUT VOLTAGE AND METHOD THEREOF

(71) Applicant: Samsung Electronics Co., Ltd., Suwon-si (KR)

(72) Inventors: Sivaneswaran SANKAR, Bengaluru (IN); Srihari Varma DATLA, Bengaluru (IN)

(73) Assignee: Samsung Electronics Co., Ltd., Suwon-si (KR)

(21) Appl. No.: 18/934,509

(22) Filed: Nov. 1, 2024

(30) Foreign Application Priority Data
Jul. 10, 2024 (IN) 202441052744

(51) Int. Cl. H02M 1/00; G11C 5/14; H02M 1/32; H02M 3/158

(52) U.S. Cl. CPC H02M 1/0022; G11C 5/147; H02M 1/32; H02M 3/158

(57) ABSTRACT

Disclosed is a switching converter. The switching converter includes a first switch and a second switch. The first switch and the second switch 104 are configured to regulate charging and discharging of an inductor. The switching converter also includes a control circuit configured to compare an output voltage of the switching converter with a threshold voltage. The control circuit is also configured to detect an overshoot in the output voltage based on the comparison. Further, the control circuit is configured to perform at least one of disable, based on the detection of the overshoot in the output voltage, each of the first and the second switch to increase a slope of an inductor discharge current flowing across the inductor, or activate a dummy load circuit such that the overshoot in the output voltage is reduced.

### CROSS-REFERENCE TO RELATED APPLICATION

This application is based on and claims priority under 35 U.S.C. § 119 to Indian Patent Application number 202441052744, filed on Jul. 10, 2024, in the Indian Patent Office, the disclosure of which is incorporated by reference herein in its entirety.

### TECHNICAL FIELD

Various example embodiments generally relate to the field of switching converters, and more specifically relate to a switching converter configured to reduce overshooting in output voltage and a method of operation of the switching converter.

### BACKGROUND

As the performance needs of complex digital devices continue to increase, it results in stringent voltage regulation limits for the power supplies (usually switching converters) of such devices. Typically, these devices draw substantially high currents (or draw high currents) from the power supply, and they are dynamically fluctuating in nature. So, it is crucial (or beneficial) to keep the voltage overshoot/undershoot at the switching converter output within regulation limits during load current transitions.

Particularly, a DC-DC switching converter generates a regulated output voltage (V_{OUT}) from an input voltage (V_{IN}). Ideally, the DC-DC switching converter maintains the output voltage (V_{OUT}) within regulation despite varying load currents. However, when a load current (I_{LOAD}) transitions from MAX to MIN, an output capacitor (C_{OUT}) of a conventional DC-DC switching converter has to sink the extra current as an inductor current (I_{ND}) of the conventional DC-DC switching converter cannot change instantaneously causing a large overshoot in output voltage (V_{OUT}). This can severely degrade the performance (or this can affect the performance) of the complex digital device connected as load to the DC-DC switching converter as the supply voltage goes out of regulation range.

Thus, it is desired to address the above-mentioned disadvantages or other shortcomings of the DC-DC switching converters.

### SUMMARY

This summary is provided to introduce a selection of concepts, in a simplified format, that are further described in the detailed description section below. This summary is neither intended to identify essential example embodiments nor is it intended for determining (or limiting) the scope of the present inventive concepts.

Some example embodiments of inventive concepts provide a switching converter. The switching converter includes a first switch connected to an input voltage (V_{IN}) source and an inductor, a second switch connected to a ground terminal and the inductor, and a control circuit connected to the first switch and the second switch, the control circuit configured to control the first switch and the second switch. The first switch and the second switch are configured to regulate charging and discharging of the inductor. The control circuit is configured to compare an output voltage (V_{OUT}) of the switching converter with a threshold voltage using at least one comparator, detect an overshoot in the output voltage (V_{OUT}) based on the comparison, and perform at least one of disable, based on the detection of the overshoot in the output voltage (V_{OUT}), each of the first switch and the second switch to increase a slope of an inductor discharge current flowing across the inductor such that the overshoot in the output voltage (V_{OUT}) is reduced, or activate a dummy load circuit connected at an output of the switching converter to reduce an overshoot in the output voltage (V_{OUT}).

Some example embodiments provide a method to reduce an overshoot in an output voltage (V_{OUT}) during load transient in a switching converter. The method includes comparing an output voltage (V_{OUT}) with a predefined threshold voltage using a comparator, detecting an overshoot in the output voltage (V_{OUT}) based on the comparison, and performing at least one of disabling, based on the detection of the overshoot in the output voltage (V_{OUT}), each of a first switch and a second switch of the switching converter such that the overshoot in the output voltage (V_{OUT}) is reduced, or enabling, based on the detection of the overshoot in the output voltage (V_{OUT}), a dummy load connected at an output of the switching converter, such that an overshoot in the output voltage (V_{OUT}) is reduced.

Some example embodiments of inventive concepts provide an electronic system, including a memory device and a power supply having a switching converter, including a first switch connected to an input voltage source and an inductor, a second switch connected to a ground terminal and the inductor, and a control circuit connected to the first switch and the second switch, the control circuit configured to control the first switch and the second switch, wherein the first switch and the second switch are configured to regulate charging and discharging of the inductor, and wherein the control circuit is configured to compare an output voltage of the switching converter with a threshold voltage using at least one comparator, detect an overshoot in the output voltage based on the comparison, and perform at least one of disable, based on the detection of the overshoot in the output voltage, each of the first switch and second switch to increase a slope of an inductor discharge current flowing across the inductor such that the overshoot in voltage is reduced, or activate a dummy load circuit connected at an output of the switching converter to reduce an overshoot in the output voltage.

### BRIEF DESCRIPTION OF THE DRAWINGS

These and other features, aspects, and advantages of the inventive concepts will become better understood when the following detailed description is read with reference to the accompanying drawings in which like characters represent like parts throughout the drawings, wherein:

FIG. 1A illustrates a block diagram of an electronic system including a DC-DC switching converter, according to an example embodiment;

FIG. 1B illustrates a schematic diagram of the DC-DC switching converter, according to an example embodiment;

FIG. 2A illustrates a schematic diagram of a first scheme of a control circuit of the DC-DC switching converter, according to an example embodiment;

FIG. 2B illustrates a schematic diagram of a second scheme of the control circuit of the DC-DC switching converter, according to an example embodiment;

FIG. 3 illustrates a circuit diagram of the DC-DC switching converter, according to an example embodiment;

FIG. 4 illustrates a timing diagram associated with the DC-DC switch converter, according to an example embodiment;

FIG. 5A illustrates behavioral characteristics of a switching converter during a load current transition, according to conventional techniques;

FIGS. 5B-5C illustrate behavioral characteristics of the switching converter during a load current transition, according to some example embodiments;

FIG. 6 is a flow diagram illustrating a method for operation of the DC-DC switching converter, according to an example embodiment; and

FIG. 7 is an exemplary flow chart of a method for operation of the DC-DC switching converter, according to an example embodiment.

Further, skilled artisans will appreciate that elements in the drawings are illustrated for simplicity and may not have necessarily been drawn to scale. For example, the flow charts illustrate some example embodiments in terms of the steps (or operations) involved to help improve understanding of some inventive concepts. Furthermore, regarding construction or assembly of some example embodiments, one or more components of some example embodiments may have been represented in the drawings by conventional symbols, and the drawings may show only those specific details that are pertinent (or beneficial) to understand some example embodiments of the present inventive concepts. Additionally, details that will be readily apparent to those of ordinary skill in the art have been omitted from the drawings.

### DETAILED DESCRIPTION

Hereinafter, reference will be made to various example embodiments illustrated in the drawings and specific language will be used to describe the same. It will nevertheless be understood that no limitation of the scope of the present inventive concepts is thereby intended, such that the present inventive concepts do not have to be configured as limited to the various example embodiments described below and may be embodied in various forms. The following various example embodiments are not provided to fully complete the present inventive concepts, but rather to fully convey the scope of the present inventive concepts to those of ordinary skill in the art.

It will be understood by those skilled in the art that the foregoing general description and the following detailed description represent some example embodiments of the inventive concepts and are not intended to be restrictive thereof.

Reference throughout this specification to “an aspect”, “another aspect” or similar language means that a particular feature, structure, or characteristic described in connection with the example embodiments is included in at least one example embodiment. Thus, appearances of the phrase “in an example embodiment”, “in some example embodiments”, “in another example embodiment”, and similar language throughout this specification may, but do not necessarily, all refer to the same example embodiment.

The terms “comprise”, “comprising”, or any other variations thereof, are intended to cover a non-exclusive inclusion, such that a process or method that comprises a list of operations does not include only those operations but may include other operations not expressly listed or inherent to such process or method. Similarly, one or more devices or sub-systems or elements or structures or components preceded by “comprises . . . a” does not, without more constraints, preclude the existence of other devices or other sub-systems or other elements or other structures or other components or additional devices or additional sub-systems or additional elements or additional structures or additional components.

Some example embodiments herein and the various features and advantageous details thereof are explained more fully with reference to the non-limiting example embodiments that are illustrated in the accompanying drawings and detailed in the following description. Descriptions of well-known components and processing techniques are omitted so as to not unnecessarily obscure the example embodiments herein. Also, the various example embodiments described herein are not necessarily mutually exclusive, as some example embodiments can be combined with one or more other example embodiments to form new example embodiments. The term “or” as used herein, refers to a non-exclusive or unless otherwise indicated. The examples used herein are intended merely to facilitate an understanding of ways in which the example embodiments herein can be practiced and to further enable those skilled in the art to practice the example embodiments herein. Accordingly, the examples should not be construed as limiting the scope of the example embodiments herein.

As is traditional in the field, example embodiments may be described and illustrated in terms of blocks that carry out a described function or functions. These blocks, which may be referred to herein as units or modules or the like, are physically implemented by analog or digital circuits such as logic gates, integrated circuits, microprocessors, micro-controllers, memory circuits, passive electronic components, active electronic components, optical components, hardwired circuits, or the like, and may optionally be driven by firmware and software. The circuits may, for example, be embodied in one or more semiconductor chips, or on substrate supports such as printed circuit boards and the like. The circuits constituting a block may be implemented by dedicated hardware, or by a processor (e.g., one or more programmed microprocessors and associated circuitry), or by a combination of dedicated hardware to perform some functions of the block and a processor to perform other functions of the block. Each block of the example embodiments may be physically separated into two or more interacting and discrete blocks without departing from the scope of the present inventive concepts. Likewise, the blocks of the example embodiments may be physically combined into more complex blocks without departing from the scope of the present inventive concepts.

The accompanying drawings are used to help easily understand various technical features and it should be understood that the example embodiments presented herein are not limited by the accompanying drawings. As such, the present specification should be construed to extend to any alterations, equivalents, and substitutes in addition to those which are particularly set out in the accompanying drawings. Although the terms first, second, etc. may be used herein to describe various elements, these elements should not be limited by these terms. These terms are generally only used to distinguish one element from another.

The phrase “DC” corresponds to “Direct Current”.

Throughout this specification, the terms “DC-DC switching converter” and “switching converter” are used interchangeably and mean the same.

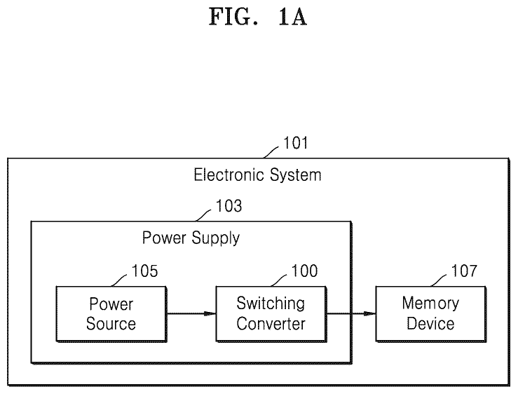

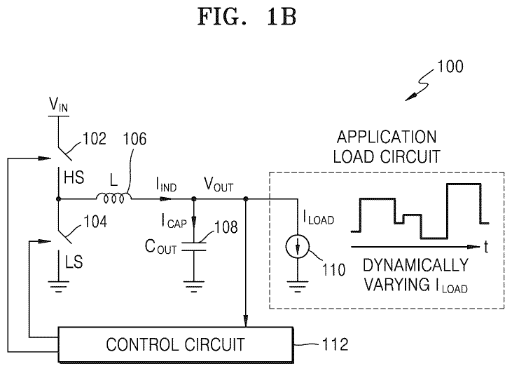

Referring to FIGS. 1A to 3, similar reference characters denote corresponding features consistently throughout the figures.

FIG. 1A illustrates a block diagram of an electronic system 101 including a switching converter 100, according to an example embodiment. The electronic system 101 may correspond to any suitable electronic device such as, but not limited to, personal computing devices, mobile communication devices, servers, and so forth. The electronic system 101 may at least include a power supply 103 including a power source 105, the switching converter (e.g., DC-DC switching converter) 100, and a memory device 107. The power source 105 may correspond to a DC power source configured to supply power for the operation of the memory device 107 and/or the electronic system 101. The switching converter (e.g., DC-DC switching converter) 100 may be configured to provide a regulated and/or stable output voltage from the power source 105 to the memory device 107. The memory device 107 may act as a load for the power source 105 and store information required for the processing of the electronic system 101. Example of the memory device 107 may include, but is not limited to, a Random Access Memory (RAM). Embodiments illustrated in FIG. 1A are exemplary and the electronic system 101 may include any suitable number of components required for performing the desired operation.

In some example embodiments, the switching converter 100 includes a first switch connected to an input voltage source and an inductor; a second switch connected to a ground terminal and the inductor; and a control circuit connected to the first switch and the second switch, wherein the control circuit configured to control the first switch and the second switch. The first switch and the second switch are configured to regulate charging and discharging of the inductor. The control circuit is configured to: compare an output voltage of the switching converter with a threshold voltage using at least one comparator; detect an overshoot in the output voltage based on the comparison; and perform at least one of—disable, based on the detection of the overshoot in the output voltage, each of the first switch and the second switch to increase a slope of an inductor discharge current flowing across the inductor such that the overshoot in the output voltage is reduced; or activate a dummy load circuit connected at an output of the switching converter to reduce an overshoot in the output voltage.

In some example embodiments, the switching converter is one of a buck converter and a boost converter. In some example embodiments, the switching converter is a buck-boost converter.

FIG. 1B illustrates a schematic diagram of the DC-DC switching converter 100 (interchangeably referred to as “the switching converter 100”), according to an example embodiment as disclosed herein. In some example embodiments, the switching converter 100 may correspond to a type of power supply circuit configured to efficiently regulate (or to regulate) the voltage supplied to complex digital devices (for example memory devices 107). For instance, memory interfaces used in memory devices 107 such as, but not limited to, RAM, require (or use) stable and specific voltage (or given voltage) levels for proper operation (or for operation), and the switching converter 100 may be configured to provide a regulated output voltage to such memory interfaces. Further, the switching converter 100 may correspond to any suitable type of the DC-DC switching converter, such as buck, boost, and buck-boost converters. The switching converter 100 may be configured to take an input voltage (V_{IN}) from a main power supply of the electronic system and generate a stabilized output voltage (V_{OUT}) for a load 110. The load 110 may correspond to the memory device 107 (as shown in FIG. 1A).

In some example embodiments, the switching converter 100 may include a first switch 102, a second switch 104, an inductor (L) 106, a capacitor (C_{OUT}) 108, and a control circuit 112. The first switch 102 may correspond to a High Side (HS) switch and the second switch 104 may correspond to a Low Side (LS) switch. The first switch 102 may be responsible for (or may be configured to) interrupting and modulating a flow of current on a high-voltage side of the switching converter 100, for instance at the input voltage (V_{IN}). In some example embodiments, the first switch 102 may have two terminals where one terminal is connected to an input voltage (V_{IN}) source and another terminal is connected to the inductor 106. Further, the first switch 102 may be configured to connect/disconnect the input voltage (V_{IN}) to the inductor 106, and/or control a current flow from the input voltage (V_{IN}) source to the inductor 106. The second switch 104 may be responsible for (or may be configured to) controlling the current flow on a low-voltage side of the switching converter 100. In some example embodiments, the second switch 104 may include two terminals where one terminal is connected to the inductor 106 and another terminal is connected to a ground terminal. For example, the first switch 102 and the second switch 104 may be configured to enable the switching converter 100 to convert one DC voltage level to another, as required by (or as may be advantageous for) the electronic system, for example, a switching operation of the first switch 102 and the second switch 104 allows regulation of the output voltage (V_{OUT}). Examples of the first switch 102 and the second switch 104 may include, but are not limited to, Metal-Oxide-Semiconductor Field-Effect Transistors (MOSFETs) switches, or other types of switches with low conduction losses.

The inductor 106 may be configured to store and release energy during the switching operation of the first switch 102 and/or the second switch 104. For example, during the switching operation of the first switch 102 and/or the second switch 104, an inductor current (I_{IND}) (also referred to as “the inductor discharge current”) flows through the inductor 106 to the output capacitor 108 and/or the load 110. In some example embodiments, during an ON state of the first switch 102, the inductor 106 stores energy, and during an OFF state of the first switch 102, the inductor 106 releases the stored energy. In some example embodiments, the inductor 106 may smoothen the output voltage (V_{OUT}) by providing a continuous flow of energy during the switching cycle of the first switch 102 and/or the second switch 104. Further, an inductance value of the inductor 106 may be selected based on a desired output voltage (V_{OUT}), the input voltage (V_{IN}), and a switching frequency of the first switch 102 and/or the second switch 104.

The output capacitor 108 is disposed (or arranged) at an output side of the switching converter and is configured to filter and stabilize the output voltage (V_{OUT}), reduce ripple, and ensure a steady power supply to the load 110. The output capacitor 108 may also charge during the ON state of the first switch 102, by receiving energy from the inductor 106. Further, during the OFF state of the first switch 102, the output capacitor 108 may discharge by supplying energy to the load 110. Further, a capacitance value of the output capacitor 108 may be selected based on a desired output voltage (V_{OUT}) ripple, a load current (I_{LOAD}), and a required transient response. The output capacitor 108 may be configured to filter out voltage fluctuations and ensure a reliable and smooth power delivery to the load 110. In some example embodiments, the load 110 may correspond to the memory interfaces.

The switching converter 100 may further include the control circuit 112. The control circuit 112 may be configured to monitor the output voltage (V_{OUT}) and adjust the switching operation of the first switch 102 and/or the second switch 104 to maintain a constant and accurate voltage level. The control circuit 112 may further be configured to implement two control schemes during an overshoot in the output voltage (V_{OUT}). For example, when the load current (I_{LOAD}) transitions from MAX to MIN, the output capacitor 108 has to sink extra current as inductor current (I_{IND}) cannot be changed instantaneously causing a large overshoot in the output voltage (V_{OUT}). Such a large overshoot in the output voltage (V_{OUT}) may degrade (or negatively affect) an overall performance of the complex digital devices (e.g., the load 110). Therefore, the control circuit 112 may be configured to reduce such an overshoot such that the output voltage (V_{OUT}) remains within the regulation limits. In some example embodiments, the control circuit 112 may be configured to compare the output voltage (V_{OUT}) of the switching converter with a predefined threshold voltage. Further, the control circuit 112 may be configured to detect the overshoot in the output voltage (V_{OUT}) based on the comparison. Moreover, the control circuit 112 may disable each of the first switch 102 and the second switch 104 to increase the slope of the inductor current (I_{IND}) flowing across the inductor 106 such that the overshoot in the output voltage (V_{OUT}) is reduced and/or activate a dummy load circuit connected at an output of the switching converter 100 to reduce an overshoot in the output voltage (V_{OUT}). The control circuit 112 may perform the aforementioned operations as a first scheme and a second scheme, which are explained in detail in the following description.

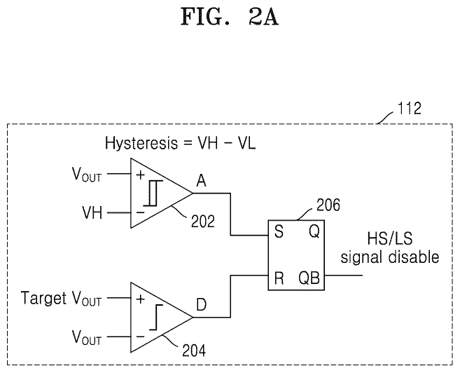

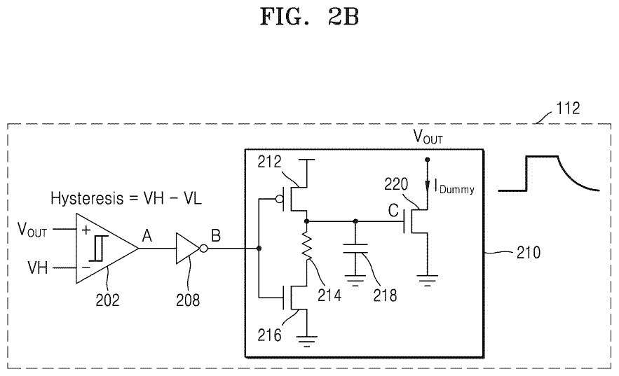

FIG. 2A illustrates a schematic diagram of the first scheme of the control circuit 112 of the DC-DC switching converter 100, according to some example embodiments disclosed herein. As per the first scheme, the control circuit 112 includes a comparator with hysteresis 202 (referred to as “the first comparator 202”), a second comparator 204, and a Set-Reset (SR) latch 206. The first comparator 202 is configured to compare the output voltage (V_{OUT}) of the switching converter 100 with the predefined threshold voltage (V_{H}) and sets the SR latch 206, as explained in detail in the following paragraphs. For example, the first comparator 202 is designed to have hysteresis which prevents (or reduces) rapid and unwanted switching (e.g., setting the SR latch 206) when an input signal (e.g., the output voltage (V_{OUT})) is near the threshold voltage (V_{H}) (or the first comparator 202 is designed to have hysteresis which prevents (or reduces) rapid and unwanted switching (e.g., setting the SR latch 206) in response to an input signal (e.g., the output voltage (V_{OUT}) being near the threshold voltage (V_{H})).

In some example embodiments, the first comparator 202 is configured to generate a high output when the output voltage (V_{OUT}) exceeds the predefined threshold voltage (V_{H}) (or the first comparator 202 is configured to generate a high output in response to the output voltage (V_{OUT}) exceeding the predefined threshold voltage (V_{H}). In some example embodiments, the output voltage (V_{OUT}) is fed to a non-inverting terminal of the first comparator 202 and the threshold voltage (V_{H}) is fed to an inverting terminal of the first comparator 202. Further, a comparison of the output voltage (V_{OUT}) with the threshold voltage (V_{H}) enables the control circuit 112 to determine if there is any overshoot in the output voltage (V_{OUT}).

The second comparator 204 is configured to compare the output voltage (V_{OUT}) with a target output voltage (Target V_{OUT}). The target output voltage (Target V_{OUT}) corresponds to the desired output voltage required for the operation of the load 110 (as shown in FIG. 1B). Therefore, when the output voltage (V_{OUT}) goes below the target output voltage (Target V_{OUT}), the second comparator 204 resets the SR latch 206 (or the second comparator 204 is configured to reset the SR latch 206 in response to the output voltage (V_{OUT}) being below the target output voltage (Target V_{OUT}). In some example embodiments, the output voltage (V_{OUT}) is fed to an inverting terminal of the second comparator 204 and the target (V_{OUT}) is fed to a non-inverting terminal of the second comparator 204. Further, a comparison of the output voltage (V_{OUT}) with the target output voltage (Target V_{OUT}) enables the control circuit 112 to maintain the output voltage (V_{OUT}) above a desired level.

The SR latch 206 is configured to enable and disable the first switch 102 and/or the second switch 104. For example, the SR latch 206 has a set terminal (labeled as “S”), a reset terminal (labeled as “R”), and output terminals (labeled as “Q” and “QB”). The first comparator 202 is connected with the SR latch 206 via the set terminal. The second comparator 204 is connected with the SR latch 206 via the reset terminal.

In some example embodiments, during the overshoot condition when the output voltage (V_{OUT}) exceeds the threshold voltage (V_{H}) (or during the overshoot condition based on the output voltage (V_{OUT}) exceeding the threshold voltage (V_{H})), the first comparator 202 generates an output “1”, for example, an output node “A” gets set to “1”. Further, during the overshoot condition, the second comparator 204 generates an output “0”, as during the overshoot condition, the output voltage (V_{OUT}) is greater than the target output voltage (Target V_{OUT}). Thus, an output node “D” of the second comparator 204 gets set to “0”. As a result, an output at the output terminal “QB” of the SR latch 206 transitions from “1” to “0”, for example, S=“1”, R=“0” results QB=“0”, this disables both the first switch 102 and the second switch 104.

In some example embodiments, by disabling both the first switch 102 and the second switch 104, the control circuit 112 increases an inductor discharge rate to reduce the overshoot in the output voltage (V_{OUT}), for example, the control circuit 112 increases a slope of the inductor current (I_{IND}) during the discharge phase. In some example embodiments, the control circuit 112 may generate enable/disable control signals for the first switch 102 and/or the second switch 104 via the output terminal (labeled as “QB”).

FIG. 2B illustrates a schematic diagram of a second scheme of the control circuit 112 of the DC-DC switching converter 100, according to some example embodiments as disclosed herein. As per the second scheme, the control circuit 112 includes the first comparator 202, an inverter circuit 208, and a dummy load circuit 210. As discussed above, the first comparator 202 is configured to perform the comparison of the output voltage (V_{OUT}) with the threshold voltage (V_{H}) to determine if there is any overshoot in the output voltage (V_{OUT}). Upon determining that there is an overshoot in the output voltage (V_{OUT}), the control circuit 112 enables the first scheme (e.g., shown in FIG. 2A) and/or the second scheme (e.g., shown in FIG. 2B), as per the requirement. As shown in FIG. 2B, the control circuit 112 includes the inverter circuit 208 (illustrated as a NOT gate) to effectively enable (or to enable) and/or disable the dummy load circuit 210. The dummy load circuit 210 may be configured to drain out excess charge and reduce overshoot in the output voltage (V_{OUT}). The dummy load circuit 210 may include a pair of transistors 212, and 216, a resistor 214, a capacitor 218, and a dummy load transistor 220. The pair of transistors 212, and 216 coupled with the resistor 214 and the capacitor 218 is configured to enable/disable the dummy load transistor 220, as per requirements. In some example embodiments, the dummy load transistor 220 is activated until the time extra charge at the output voltage (V_{OUT}) is completely drained out (or is drained out). Further, the dummy load transistor 220 is gradually turned off using the pair of transistors 212, and 216 coupled with the resistor 214 and the capacitor 218 to avoid further overshoot in the output voltage (V_{OUT}). For example, as discussed above, during the overshoot condition, the output node “A” of the first comparator 202 gets set to “1”, this results in setting a node “C” as “1” and thereby enables the dummy load transistor 220.

Post overshoot condition, the output voltage (V_{OUT}) may start decreasing, and when the output voltage (V_{OUT}) falls below a low threshold voltage (V_{L}) (or based on the output (V_{OUT}) falling below a low threshold voltage (V_{L})), the first comparator 202 generates an output “0”, for example, the output node “A” gets set to “0”. As a result, the node “C” transitions from ‘1’ to ‘0’ gradually due to the presence of the resistor 214 and the capacitor 218 and disables the dummy load transistor 220. This prevents (or reduces) further overshoot in the output voltage (V_{OUT}) overshoot due to the withdrawal of the dummy load circuit 210. Further, when the output voltage (V_{OUT}) continues to fall and when the output voltage (V_{OUT}) falls below the target output voltage (Target V_{OUT}), the second comparator 204 generates an output “1”, for example, the output node “D” gets set to “1” (or the second comparator 204 is configured to generate an output “1”, for example, the output node “D” gets set to “1” in response to the output voltage (V_{OUT}) falling below the target output voltage (Target V_{OUT})). As a result, an output at the output terminal “QB” of the SR latch 206 transitions from “0” to “1”, i.e., S=“0”, R=“1” results QB=“1”, this erases a control signal for disabling the first switch 102 and the second switch 104, and the switching converter 100 operates in normal mode. This cycle repeats whenever there is a large overshoot on the output voltage (V_{OUT}).

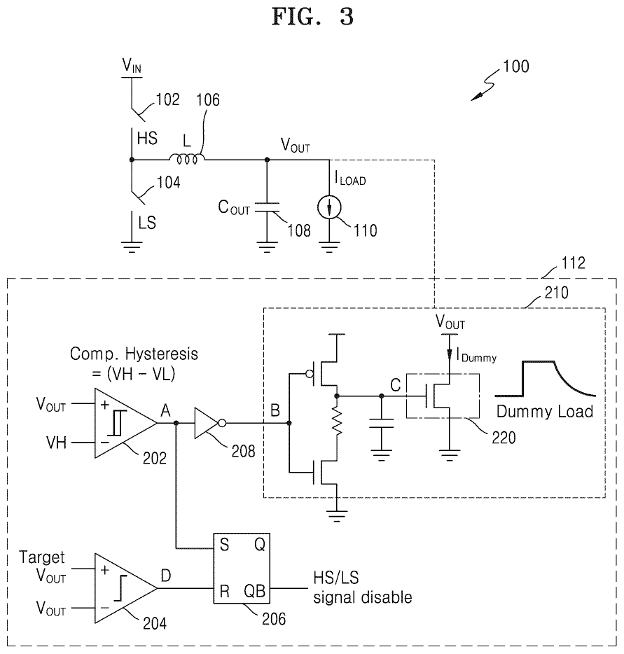

FIG. 3 illustrates a circuit diagram of the DC-DC switching converter 100, according to some example embodiments as disclosed herein. FIG. 3 illustrates various components of the switching converter 100 within an integration of the first scheme (e.g., as shown in FIG. 2A) and the second scheme (e.g., as shown in FIG. 2B) of the control circuit 112. FIG. 3 illustrates that the first scheme and the second scheme of the control circuit 112 are integrated at node “A” via the inverter circuit 208. In some example embodiments, the second scheme acts as a fallback strategy to reduce overshoot when the increasing slope of the inductor current (I_{IND}) does not effectively reduce (or does not reduce) the overshoot in the output voltage (V_{OUT}) (or the second scheme acts as a fallback strategy to reduce overshoot based on the increasing slope of the current (I_{IND}) not reducing the overshoot in the output voltage (V_{OUT})). Further, as illustrated, the dummy load transistor 220 is connected at an output of the switching converter 100. The dummy load transistor 220 gets enabled during an overshoot condition resulting in a flow of dummy current (I_{DUMMY}) across the dummy load transistor 220 resulting in a reduction in the overshoot of the output voltage (V_{OUT}).

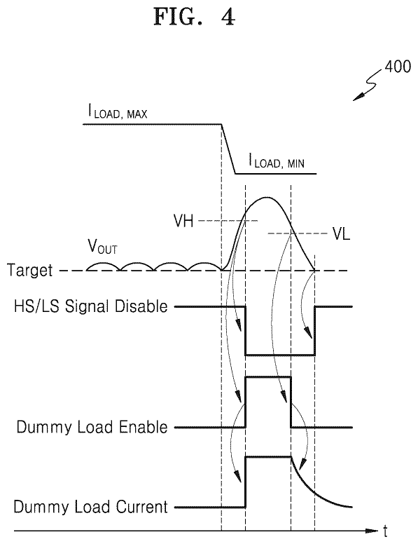

FIG. 4 illustrates a timing diagram 400 associated with the DC-DC switching converter 100, according to some example embodiments as disclosed herein. As shown, when the load current (I_{LOAD}) suddenly transits (or transits) from MAX to MIN, a sudden spike (or a spike) in output voltage (V_{OUT}) can be seen (or a spike in output voltage (V_{OUT}) can be seen in response to the load current (I_{LOAD}) transiting from MAX to MIN. In some example embodiments, when the output voltage (V_{OUT}) crosses the threshold voltage (V_{H}) (or based on the output voltage (V_{OUT}) crossing the threshold voltage (V_{H})), the control circuit 112 considers the scenario as the output voltage (V_{OUT}) overshoot condition. As discussed previously, the first comparator 202 may determine the output voltage (V_{OUT}) overshoot condition. Further, as discussed previously, the second comparator 204 enables (or may enable the) control circuit 112 to maintain the output voltage (V_{OUT}) above the target output voltage (V_{OUT}), as also shown in FIG. 4. During the overshoot condition, the control circuit 112 disables (or may disable) both the HS switch (e.g., the first switch 102) and the LS switch (e.g., the second switch 104) and/or enables (or may enable) the dummy load (e.g., the dummy load circuit 210). Further, the timing diagram 400 illustrates that when both the HS switch (e.g., the first switch 102) and the LS switch (e.g., the second switch 104) are disabled, the output voltage (V_{OUT}) starts decreasing (or the output voltage (V_{OUT}) starts decreasing in response to the HS switch (e.g., the first switch 102) and the LS switch (e.g., the second switch 104) being disabled. Similar observations can be seen during the enabling of the dummy load. However, when the output voltage (V_{OUT}) is below a lower threshold voltage (V_{L}), the control circuit 112 gradually disables (or disables) the dummy load circuit 210 resulting in a gradual decrease (or in a decrease) in the dummy load current (I_{DUMMY}) (or the control circuit 112 disables the dummy load circuit 210 resulting in a decrease in the dummy load current (I_{DUMMY}) based on the output voltage (V_{OUT}) being below a lower threshold voltage (V_{L})).

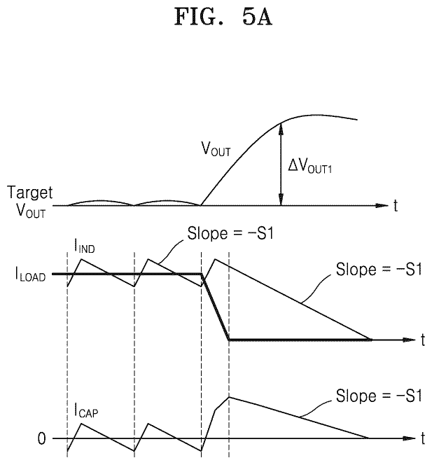

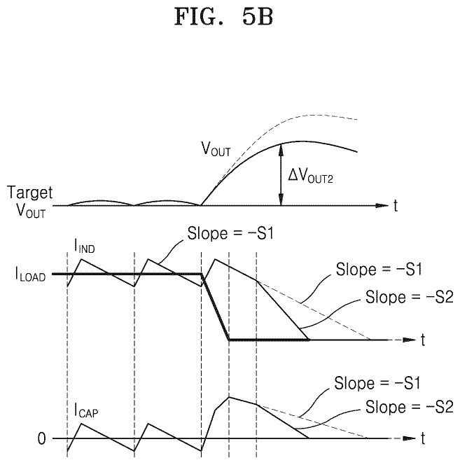

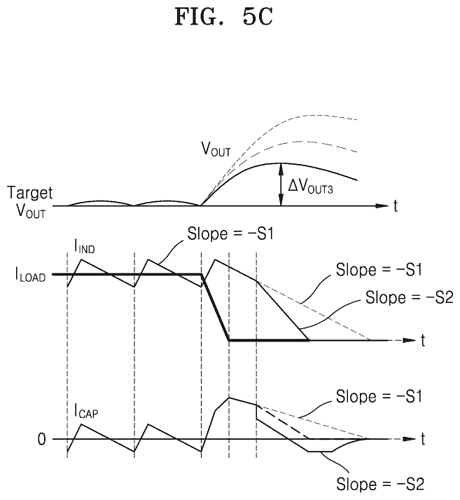

FIG. 5A illustrates behavioral characteristics of a switching converter when a load current (I_{LOAD}) transitions from MAX to MIN (or based on a load current (I_{LOAD}) transitioning from MAX to MIN), according to conventional techniques. For example, immediately after the transition (or after the transition), an inductor current (I_{IND}) does not become zero instantaneously but rather discharges at a rate denoted by slope “−S1”. This current entirely flows through an output capacitor (C_{OUT}) 108 resulting in a voltage overshoot of ΔVOUT1 at an output of the switching converter 100.

FIGS. 5B-5C illustrate behavioral characteristics of the switching converter 100 during a load current (I_{LOAD}) transition from MAX to MIN, according to some example embodiments disclosed herein. For example, FIG. 5B illustrates that post overshoot detection, when (or based on) both the first switch 102 (e.g., the HS switch) and the second switch 104 (e.g., the LS switch) are (or being) disabled, the voltage across the inductor 106 will increase thereby discharging the energy stored in the inductor 106 at a faster rate as denoted by slope=−S2. This results in lower voltage overshoot ΔVOUT2 as lesser charge is dumped onto the output capacitor (C_{OUT}) 108. FIG. 5C illustrates post-overshoot detection, when (or based on) the dummy load transistor 220 is also enabled along with disabling of the first switch 102 (e.g., the HS switch) and the second switch 104 (e.g., the LS switch), the charge dumped onto the output capacitor (C_{OUT}) 108 gets lowered even further as some of the charge gets diverted to the dummy load transistor 220. This results in the lowest voltage overshoot (ΔVOUT3) among all the scenarios illustrated in FIGS. 5A-5C.

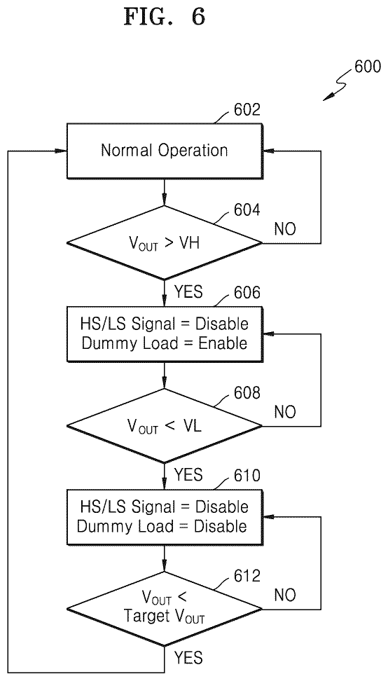

FIG. 6 is a flow diagram illustrating a method 600 for the operation of the DC-DC switching converter 100, according to an example embodiment.

At operation 602, the switching converter 100 may perform a normal operation, for example, to regulate the output voltage (V_{OUT}), in accordance with the requirement of the switching converter 100. At operation 604, the switching converter 100 and/or the control circuit 112 may determine whether the output voltage (V_{OUT}) exceeds the predefined threshold voltage (V_{H}). In case the output voltage (V_{OUT}) does not exceed the predefined threshold voltage (V_{H}), the switching converter 100 may perform the normal operation, as shown in step 602.

However, in case the output voltage (V_{OUT}) exceeds the predefined threshold voltage (V_{H}), the switching converter 100 and/or the control circuit 112 may disable the first switch 102 (e.g., the HS switch) and the second switch 104 (e.g., the LS switch) and/or enable the dummy load circuit 210, as shown by operation 606.

At operation 608, the switching converter 100 and/or the control circuit 112 may determine whether the output voltage (V_{OUT}) is below the lower predefined threshold voltage (V_{L}). Upon determining, the output voltage (V_{OUT}) is above the lower predefined threshold voltage (V_{L}), the switching converter 100 and/or the control circuit 112 may keep the first switch 102 (e.g., the HS switch) and the second switch 104 (e.g., the LS switch) in a disabled state and/or the dummy load circuit 210 in an enabled state, as performed in operation 606.

However, upon determining that the output voltage (V_{OUT}) is below the lower predefined threshold voltage (V_{L}), the switching converter 100 and/or the control circuit 112 may keep the first switch 102 (e.g., the HS switch) and the second switch 104 (e.g., the LS switch) in the disabled state and disable the dummy load circuit 210, as shown in operation 610.

At operation 612, the switching converter 100 and/or the control circuit 112 may determine if the output voltage (V_{OUT}) is below the target output voltage. Upon determining that the output voltage (V_{OUT}) is above the target output voltage, keep the first switch 102 (e.g., the HS switch) and the second switch 104 (e.g., the LS switch) in the disabled state and the dummy load circuit 210 in a disabled state, as shown in operation 610.

However, upon determining that the output voltage (V_{OUT}) is below the target output voltage, the switching converter 100 returns to the normal mode of operation, for example, operation 602 allowing the control circuit 112 to operate first switch 102 and second switch 104 to regulate the output voltage (V_{OUT}).

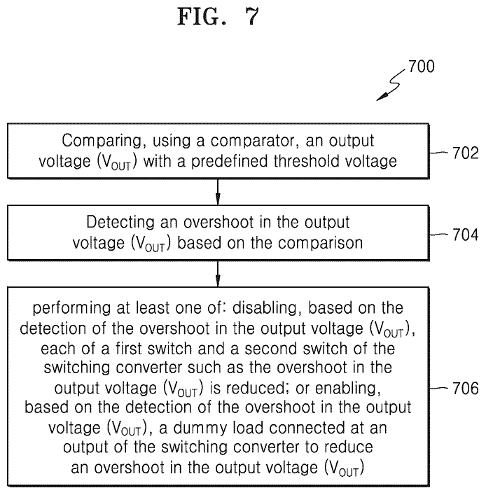

FIG. 7 is a flow chart of a method 700 for the operation of the DC-DC switching converter 100, according to an example embodiment.

At operation 702, the method 700 includes comparing, using the first comparator 202, an output voltage (V_{OUT}) with a predefined (or desired) threshold voltage.

At operation 704, the method 700 includes detecting an overshoot in the output voltage (VOUT) based on the comparison.

At operation 706, the method 700 includes performing at least one of disabling, based on the detection of the overshoot in the output voltage (V_{OUT}), each of a first switch and a second switch 104 of the switching converter 100 such as the overshoot in the output voltage (V_{OUT}) is reduced, and/or enabling, based on the detection of the overshoot in the output voltage (V_{OUT}), a dummy load connected at an output of the switching converter 100 to reduce an overshoot in the output voltage (V_{OUT}).

Thus, the present inventive concepts enable the proposed schemes of the control circuit 112 based on overshoot on the output voltage (V_{OUT}), thereby enabling the switching converter 100 to achieve a minimum overshoot. Further, the proposed control circuit may be employed in any DC-DC switching converters, thereby providing support for a wide range of applications/systems.

The various actions, acts, blocks, operations, or the like in the flow diagrams may be performed in the order presented, in a different order, or simultaneously. Further, in some example embodiments, some of the actions, acts, blocks, operations, or the like may be omitted, added, modified, skipped, or the like without departing from the scope of the present inventive concepts.

Unless otherwise defined, all technical and scientific terms used herein have the same meaning as commonly understood by one ordinary skilled in the art to which this invention belongs. The system, methods, and examples embodiments provided herein are illustrative only and not intended to be limiting.

While specific language has been used to describe the present inventive concepts, any limitations arising on account thereto, are not intended. As would be apparent to a person of ordinary skill in the art, various working modifications may be made to the method to implement the present inventive concepts as taught herein. The drawings and the forgoing description give examples of some example embodiments. Those skilled in the art will appreciate that one or more of the described elements may well be combined into a single functional element. Alternatively or additionally, certain elements may be split into multiple functional elements. Elements from one example embodiment may be added to another example embodiment.

Some example embodiments disclosed herein can be implemented using at least one hardware device and performing network management functions to control the elements.

The foregoing description of some example embodiments will so fully reveal the general nature of some example embodiments herein that others can, by applying current knowledge, readily modify and/or adapt for various applications such specific example embodiments without departing from generic concepts, and, therefore, such adaptations and modifications should and are intended to be comprehended within the meaning and range of equivalents of the example embodiments disclosed herein. It is to be understood that the phraseology or terminology employed herein is for the purpose of description and not of limitation. Therefore, while some example embodiments herein have been described, those skilled in the art will recognize that some example embodiments herein can be practiced with modification within the scope of the present inventive concepts as described herein.

We claim:

1. A switching converter, comprising:
a first switch connected to an input voltage source and an inductor;
a second switch connected to a ground terminal and the inductor; and
a control circuit connected to the first switch and the second switch, the control circuit configured to control the first switch and the second switch,
wherein the first switch and the second switch are configured to regulate charging and discharging of the inductor, and
wherein the control circuit is configured to
compare an output voltage of the switching converter with a threshold voltage using at least one comparator;
detect an overshoot in the output voltage based on the comparison; and
perform at least one of
disable, based on the detection of the overshoot in the output voltage, each of the first switch and the second switch to increase a slope of an inductor discharge current flowing across the inductor such that the overshoot in the output voltage is reduced; or
activate a dummy load circuit connected at an output of the switching converter to reduce an overshoot in the output voltage.

2. The switching converter of claim 1, wherein the first switch corresponds to a High Side switch and the second switch corresponds to a Low Side switch.

3. The switching converter of claim 1, wherein the control circuit comprises a first comparator with hysteresis configured to compare the output voltage of the switching converter with the threshold voltage, and a second comparator configured to compare the output voltage with a target voltage, and wherein the first comparator with hysteresis is configured to generate a high output in response to the output voltage exceeding the threshold voltage, and the second comparator is configured to remain at a low output, that disables each of the first switch and the second switch.

4. The switching converter of claim 1, wherein the control circuit comprises a Set-Reset latch coupled with the at least one comparator, wherein the SR latch is configured to control the first switch and the second switch, and regulate the charging and discharging of the inductor.

5. The switching converter of claim 1, wherein after activating the dummy load circuit, the control circuit is configured to:
disable the dummy load after the output of a first comparator with hysteresis goes to zero, such that an unnecessary overshoot in the output voltage is prevented.

6. A method to reduce an overshoot in an output voltage during load transient in a switching converter, the method comprising:
comparing an output voltage with a threshold voltage using a comparator;
detecting an overshoot in the output voltage based on the comparison; and
performing at least one of
disabling, based on the detection of the overshoot in the output voltage, each of a first switch and a second switch of the switching converter such that the overshoot in the output voltage is reduced; or
enabling, based on the detection of the overshoot in the output voltage, a dummy load connected at an output of the switching converter, such that an overshot in the output voltage is reduced.

7. The method of claim 6, wherein the first switch corresponds to a High Side switch and the second switch corresponds to a Low Side switch.

8. The method of claim 6, wherein the first switch is connected to an input voltage source and an inductor, and the second switch is connected to a ground terminal and the inductor.

9. The method of claim 6, wherein after enabling the dummy load, the method comprises:
disabling the dummy load after the output of a first comparator with hysteresis goes to zero, such that an unnecessary overshoot in the output voltage is prevented.

10. An electronic system, comprising:
a memory device; and
a power supply having a switching converter;
wherein the switching converter includes
a first switch connected to an input voltage source and an inductor;
a second switch connected to a ground terminal and the inductor; and
a control circuit connected to the first switch and the second switch, the control circuit configured to control the first switch and the second switch,
wherein the first switch and the second switch are configured to regulate charging and discharging of the inductor, and
wherein the control circuit is configured to
compare an output voltage of the switching converter with a threshold voltage using at least one comparator;
detect an overshoot in the output voltage based on the comparison; and perform at least one of
disable, based on the detection of the overshoot in the output voltage, each of the first switch and the second switch to increase a slope of an inductor discharge current flowing across the inductor such that the overshoot in the output voltage is reduced; or
activate a dummy load circuit connected at an output of the switching converter to reduce an overshoot in the output voltage.

11. The electronic system of claim 10, wherein the memory device includes a memory interface comprising a Random Access Memory (RAM).

12. The electronic system of claim 11, wherein the switching converter is configured to provide a regulated output voltage to the memory device.

13. The electronic system of claim 10, wherein the switching converter is a DC-DC switching converter.

14. The electronic system of claim 13, wherein the switching converter is one of a buck converter and a boost converter.

15. The electronic system of claim 10, wherein the switching converter is a buck-boost converter.
